(19) United States
(12) Patent Application Publication
(10) Pub. No.: US 2015/0223576 A1
(43) Pub. Date: Aug. 13, 2015

(54) System and Method For Dynamic Jewelry

(71) Applicant: Raj Vora, Chino Hills, CA (US)

(72) Inventor: Raj Vora, Chino Hills, CA (US)

(21) Appl. No.: 14/619,771

(22) Filed: Feb. 11, 2015

Related U.S. Application Data
(60) Provisional application No. 61/939,076, filed on Feb. 12, 2014.

(51) Int. Cl. A44C 15/00; F21V 23/04; F21V 23/00; H05K 1/18; F21V 33/00; F21L 4/08

(52) U.S. Cl. CPC A44C 15/0015; F21V 33/0008; F21L 4/08; F21V 23/005; H05K 1/189; F21V 23/045; F21Y 2111/004

(57) ABSTRACT

A system and method that activates light emission elements controlled by a processor using rigid, rigid-flex, or flex circuitry that causes the light emission elements to illuminate in dynamic patterns, colors, or arrangements based on algorithms that map sensory data captured by a plurality of sensors, such as musical, biometric, behavioral, environmental, visual, or kinetic data sensors. These dynamic illumination patterns or arrangements can coordinate with the user's outfit, environment, motions, emotions, or physiological state. The system and method could be employed in various pieces of curved or straight jewelry such as bracelets, headbands, hair clips, necklaces, choker necklaces, and other consumer products as appropriate. The system can also generate dynamic sequences used for functions other than illumination, for example vibration or behavioral choices, such as whether or not to go outside based on pollution readings analyzed by the processor utilizing environmental sensor data.

### CROSS REFERENCE TO RELATED APPLICATION

This application claims priority to U.S. Provisional Application No. 61/939,076 filed on Feb. 12, 2014, the disclosure of which, including any materials incorporated by reference therein, is incorporated herein by reference in its entirety.

### BACKGROUND OF THE INVENTION

The wearing of jewelry can be described as a method of self-expression that combines physical objects and their visual effects in such a way as to coordinate the jewelry with the wearer's overall look and the wearer's environment. For this reason, jewelry pieces are not only evaluated in isolation, they are inevitably also chosen for wearing based on their relationship to the wearer's outfit and intended environment.

The use, manipulation, and interplay with light plays an important role in jewelry design and wearing. Diamonds, precious metals, precious stones, or indeed any item intended to be worn as jewelry has some relationship with light that plays an integral part in the jewelry's overall effect.

Therefore, optimal jewelry design and function takes into account the jewelry piece's ability to interact with light, relationship with the wearer's environment, and ability to compliment the wearer's look and outfit.

In an effort to address these needs, some designers have integrated light sources and corresponding electronic circuitry directly into jewelry so as to control and provide the light source for these interactions. Other designers have created jewelry that can be worn differently or adjusted to coordinate with different colors or types of outfits. Still other designers have created pieces that are adjustable, interchangeable, or variable so as to be appropriate to use in a variety of settings, from formal to casual.

However, the current jewelry available to users that incorporates lights and electronic circuitry is severely handicapped and effectively unappealing to users. Such pieces lack a truly dynamic and interactive interface that will allow the jewelry to interact with its environment by processing environmentally-derived data, such as ambient sounds, music, or speech, along with visual and wireless data.

There have been many devices and objects that have illumination, such as, light emitting diodes (LEDs) placed on or in them. For example, shoes that illuminate in the dark when the user compresses a piezoelectric device to produce electricity while walking Generally, however, these devices are usually reserved for males and younger children and youths. Fine jewelry, while having its own sparkle, does not currently have any means of providing women with the same illuminating enjoyment that others have. Thus, there remains a need for illuminating jewelry that can accommodate either a flat or a curved design and that can process and respond to auditory, visual, and wireless data to enhance user experience with sophisticated color effects that respond to this data, including systems that operate autonomously and systems that are associated with wired or wireless computer networks.

### SUMMARY OF THE INVENTION

The present invention relates to a system and method for illuminating jewelry, and more particularly to a system that illuminates a jewelry device according to environmental, biometric, user-generated, and/or predetermined data, and also to a jewelry device that houses, displays, and employs the present invention.

In one embodiment, a system may gather data from a plurality of biometric and environmental sensors, such as but not by way of limitation to a microphone and an accelerometer, in addition to, in conjunction with, or instead of data from predetermined sources, user generated sources, Bluetooth or other wirelessly enabled sources, then may process this data using algorithms and may direct the system's light emitting diodes (LEDs) to illuminate in colors or patterns to match or compliment the user's outfit or environment. In another embodiment, a device employing the system illuminates according to the system's process.

The present invention may utilize a processor mounted on rigid, flex, or rigid-flex circuitry to accomplish these tasks. The present invention may also utilize an exterior housing arranged in a design that allows the LEDs or other light emission elements, to be visible from a vantage point outside the system and method without exposing the circuitry to view.

### BRIEF DESCRIPTION OF THE DRAWINGS

These and other features, aspects and advantages of the present invention will become better understood with regard to the following description, appended claims, and accompanying figures where:

FIG. 1. is a block diagram of one non-limiting embodiment of the disclosure showing the overall sequence of the system and method.

FIG. 2. is a block diagram of one non-limiting embodiment of the disclosure showing the overall sequence of the system and method as it pertains to an example embodiment (Example Embodiment A).

FIG. 3. is a block diagram of one non-limiting embodiment of the disclosure showing the overall sequence of the system and method as it pertains to a second example embodiment (Example Embodiment B).

FIG. 4A. is one non-limiting embodiment of the disclosure disclosing an exploded view of the system and method as applied or adapted to a curved device for dynamic jewelry.

FIG. 4B. is one non-limiting embodiment of the disclosure disclosing an exploded view of the system and method as applied or adapted to a curved device for dynamic jewelry that depicts the curved device of FIG. 4A with modifications.

FIG. 5. is one non-limiting embodiment of the disclosure disclosing a side view of an exploded view of Embodiment C of the system and method as applied or adapted to a curved device for dynamic jewelry.

FIG. 6. is one non-limiting embodiment of the disclosure disclosing a top view of an exploded view of Embodiment C of the system and method as applied or adapted to a curved device for dynamic jewelry.

FIG. 7. is one non-limiting embodiment of the disclosure disclosing the system and method as applied or adapted to a device for dynamic jewelry containing a hinge.

FIG. 8. is one non-limiting embodiment of the disclosure disclosing a side view of a layered structure of the system and method as applied or adapted to a curved device for dynamic jewelry.

FIG. 9. is one non-limiting embodiment of the disclosure disclosing the system and method as applied or adapted to a curved device for dynamic jewelry depicting the circuitry as separated from the exterior housing.

### DETAILED DESCRIPTION

The present invention overcomes the limitations of the prior art by providing a system and method for dynamic jewelry enhancements. The system can be applied or adapted to a variety of jewelry, for example, bracelets, necklaces, watches, earrings, hairpins, tiaras, armlets, etc. Jewelers will now have the capability of making enhanced jewelry that will go with any outfit and any social setting from a party to a cotillion. Further, the system provides that these enhanced jewelry features can respond to data derived from environmental sensors and change their appearance accordingly, such as by displaying an illumination sequence or pattern, or alerting the user to information.

All dimensions specified in this disclosure are by way of example only and are not intended to be limiting. Further, the proportions shown in these Figures are not necessarily to scale. As will be understood by those with skill in the art with reference to this disclosure, the actual dimensions and proportions of any system, any device or part of a system or device disclosed in this disclosure will be determined by its intended use.

Systems and devices that implement the embodiments of the various features of the invention will now be described with reference to the drawings. The drawings and the associated descriptions are provided to illustrate potential embodiments of the invention and not to limit the scope of the invention. Reference in the specification to “one embodiment” or “an embodiment” is intended to indicate that a particular feature, structure, or characteristic described in connection with the embodiment is included in at least an embodiment of the invention. The appearances of the phrase “in one embodiment” or “an embodiment” in various places in the specification are not necessarily all referring to the same embodiment.

Throughout the drawings, reference numbers are re-used to indicate correspondence between referenced elements. In addition, the first digit of each reference number indicates the figure where the element first appears.

As used in this disclosure, except where the context requires otherwise, the term “comprise” and variations of the term, such as “comprising”, “comprises” and “comprised” are not intended to exclude other additives, components, integers or steps.

In the following description, specific details are given to provide a thorough understanding of the embodiments. However, it will be understood by one of ordinary skill in the art that the embodiments may be practiced without these specific detail. Well known circuits, structures and techniques may not be shown in detail in order not to obscure the embodiments. For example, circuits may be shown in block diagrams in order not to obscure the embodiments in unnecessary detail.

Furthermore, the term “algorithm” or “algorithms” are to be read as encompassing any equivalent processing or computing method. In addition, “display signal” is to be read as any signal capable of conveying information to a display element such that the display element can make at least one display change in response to the display signal.

Also, it is noted that the embodiments may be described as a process that is depicted as a flowchart, a flow diagram, a structure diagram, or a block diagram. Although a flowchart may describe or depict the operations as a sequential process, many of the operations can be performed in parallel or concurrently. In addition, the order of the operations may be rearranged. A process is terminated when its operations are completed. A process may correspond to a method, a function, a procedure, a subroutine, a subprogram, etc. When a process corresponds to a function, its termination corresponds to a return of the function to the calling function or the main function.

Furthermore, the term “Bluetooth chip” is herein used as an example of any wireless communication technology or system that can transmit and receive transmissions of data or communications between the system and method and an outside data processing element, such as a computer, mobile device, or mobile device application. The term “Bluetooth chip” is therefore to be interpreted as including any and all equivalents or equivalent systems.

Moreover, a storage element may represent one or more devices for storing data, including read-only memory (ROM), random access memory (RAM), magnetic disk storage mediums, optical storage mediums, flash memory devices and/or other non-transitory machine readable mediums for storing information. The term “machine readable medium” includes, but is not limited to portable or fixed storage devices, optical storage devices, wireless channels and various other non-transitory mediums capable of storing, comprising, containing, executing or carrying instruction(s) and/or data.

Moreover, the term “Li-Polymer Battery” and other references to batteries are herein intended to refer to any power source, whether rechargeable or single-use, in any storage or voltage range, capable of powering the system and/or device and of any dimensions or designs configured to facilitate the battery's functionality. Any references to batteries are herein intended to not be limiting and to include equivalents.

Furthermore, embodiments may be implemented by hardware, software, firmware, middleware, microcode, or a combination thereof. When implemented in software, firmware, middleware or microcode, the program code or code segments to perform the necessary tasks may be stored in a machine-readable medium such as a storage medium or other storage(s). One or more than one processor may perform the necessary tasks in series, distributed, concurrently or in parallel. A code segment may represent a procedure, a function, a subprogram, a program, a routine, a subroutine, a module, a software package, a class, or a combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted through a suitable means including memory sharing, message passing, token passing, network transmission, etc. and are also referred to as an interface, where the interface is the point of interaction with software, or computer hardware, or with peripheral devices.

The term “mobile device application” is here used to refer to any external computer, whether wired or wireless, including but not limited to a smart phone, a desktop or laptop computer, internet-based application, or other computer application capable of transmitting to and/or receiving transmissions from the present system and method.

The term LED, as used in this disclosure, refers to any light emitting element, including light emitting diodes, electro-luminescent wire, electro-luminescent strips, electro-luminescent sheets, a monochrome light emitting diode, optical wirings, light tubes, light pipe, or a multi-color light emitting diode.

The term “dynamic” refers to the interaction between the system and method and processed data that generates a unique signal, outcome, data set, set of instructions, or other output that is a result of the system and method's algorithmic processing of data and may, but is not required to be, a unique output based on real-time and/or changing data captured from the user's environment, physiological state or biometrics, movement or other source as processed by the system and method. Thus, “dynamic” refers to outcomes that are not predetermined, but rather are the product of the system and method operating using, at least in part, newly-acquired data, applying the system and method's algorithms, and deriving a unique output therefrom.

Furthermore, the term “information” as used in the present disclosure refers to any data, signal, impression, or other information capable of capture by a sensor or other data-gathering element and can be used interchangeably with the words “data” or “signal.” Such information can include, by way of illustration and not of limitation, information derived from the sensor or user's environment, such as sound, light, visuals or images, external movement, vibrations, gravitational forces, or other such information, or can include information derived via a sensor of a user's biometric condition, such as by illustration but not by way of limitation to the user's pulse, skin temperature, circadian rhythms, or other biometric data. Such information could also include, by illustration but not by way of limitation, information regarding the sensor or user's movement, or any other data capable of capture by a sensor or data-gathering device.

Furthermore, the term “information signal” is here used to refer to any transmission, signal, or communication of information between any two devices or entities capable of sending and/or receiving an information signal. In addition, when an information signal contains a specific form, type, or element of information, it is herein referred to as the type of information followed by the word “signal.” For example, information as used in this disclosure that contains information concerning light emission is herein referred to as a “light emission signal.”

Moreover, the terms “communicating relationship” or “communicating arrangement” may refer to any relationship between two or more elements wherein each or both of the elements have the capacity to send or transmit, or both, one or more signals or transmissions containing data to, from, or between the elements.

The term “providing” can include but is not limited to include the process whereby an element is selected if necessary, arranged or configured if necessary, attached if necessary, powered on if necessary, activated if necessary, and connected via either wireless or wired connection with another element if necessary.

Various embodiments provide a system and method for dynamic jewelry. One embodiment of the present invention provides a system for dynamic jewelry. In another embodiment, there is provided a method for using the system. The system and method will now be disclosed in detail.

In one or more non-limiting embodiments, the present system and method begins by providing one or more circuit board elements, one or more processor elements, one or more battery elements, one or more sensor elements, and one or more light emission elements. The processor element is in communicating relationship with the circuit board elements, the battery elements, the sensor elements, and the light emission elements. The battery element is in a communicating relationship with the processor.

The system and method, in one non-limiting embodiment then captures information using one or more of the sensor elements. This information is then transmitted from the sensor element in the form of an information signal to the processor element via a circuit or circuit board, a wired or wireless communication, or other connection form as necessary.

The processor element then applies one or more algorithms to the information signal, interprets or processes the results of this application, and creates a light emission signal based on the information signal. In one non-limiting embodiment, this application and processing may result in a light emission signal that is unique, based on real-time information and data gathered from the sensor element, not predetermined, and specific to the user's circumstance in that real-time setting. In one non-limiting embodiment, the light emission signal may be thought of as translating or interpreting the information captured by the sensor into one or more light emission signals. In one non-limiting embodiment, and by way of example and not of limitation, the resulting light emission signal could encode instructions for a light emission pattern that, in real-time, corresponds to, mimics or mirrors, inverts or counters, or otherwise responds to the user's sonic or musical environment, the user's outfit, the user's mood or physiological state, or the user's motions or movement.

This light emission signal is then sent from the processor element to a light emission element by way of a circuit board, this circuit board being either a flex circuit board, a rigid circuit board, a rigid-flex circuit board, or an equivalent signal transmission element. Those of skill in the art will recognize that the wired or wireless pathway between the processor and the light emission element is capable of various configurations both of communicating elements and pathways.

The light emission element then receives the light emission signal and may illuminate, by way of illustration and not of limitation, in a way, manner, sequence, color, color pattern, illumination pattern, or other form of illumination in conformity with the directions in the light emission signal. The light emission element may be attached or connected to light diffusers or other light directing or affecting elements.

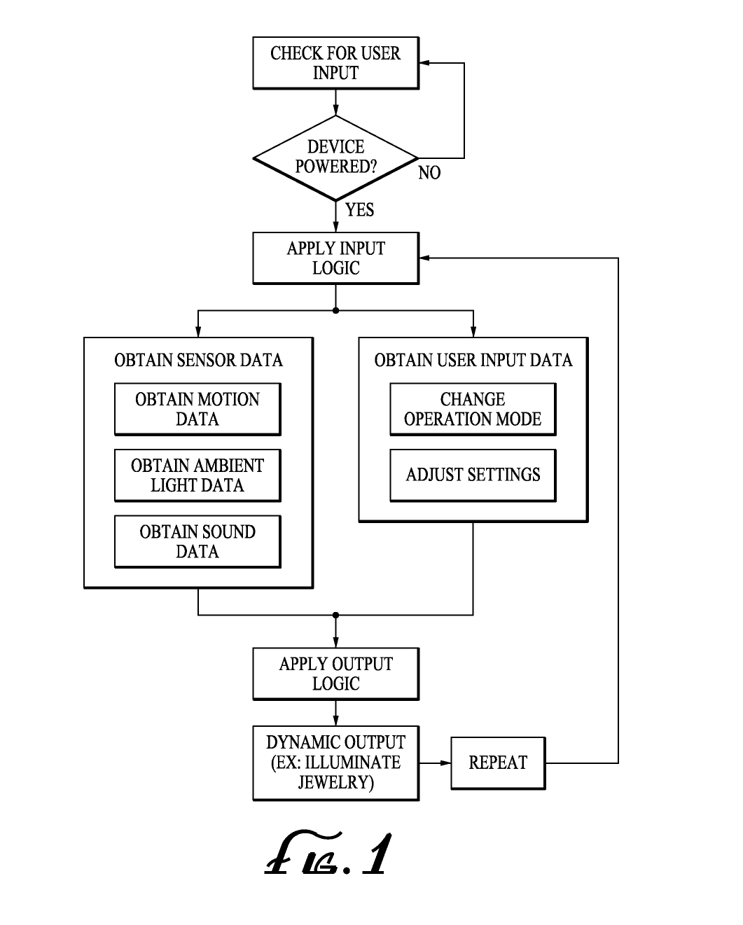

Referring now to FIG. 1, one non-limiting embodiment of a system and method for dynamic jewelry is shown in block diagram. By way of illustration and not of limitation, FIG. 1 discloses an overview of the system. In one embodiment, once the device is powered on, the system checks for data input. Based on the form of the input, the system may apply two pathways of data intake and analysis, operating continuously as the system requires. In one pathway, the system may obtain data from sensors, such data including motion data, visual data, ambient light data, musical and/or sound data, and such sensors including any number of biometric, environmental, kinetic, predetermined, wired or wireless sensors, or other forms of sensors. In the other pathway, direct input from the user, such as a mode change, an on/off change or similar input, provides the required data. Based on this data, the system then applies the system's output logic. This output data maps this data to algorithms in such a way as to provide for illumination patterns based on these algorithms or other processing methods, so that the illumination or other system responses are synched or otherwise dynamically affected by the music, ambient sounds, speech, or other environmental sound data elements as detected by the system using a myriad of sensors. Thus, in one embodiment, the illumination patterns are not pre-determined but rather are determined by the system's algorithms or other processing methods as applied to the environmental sound data being processed by the system. In another embodiment, the system uses algorithms or other suitable elements to not only match the illumination to environmental sound data, but also to movement data as detected by a myriad of sensors, or a combination of movement and sound data. In another embodiment, the system uses algorithms to match biometric data, taken either in isolation or in combination with either sound and/or movement data, to patterns of illumination. The system then repeats the sequence, beginning at the input logic stage.

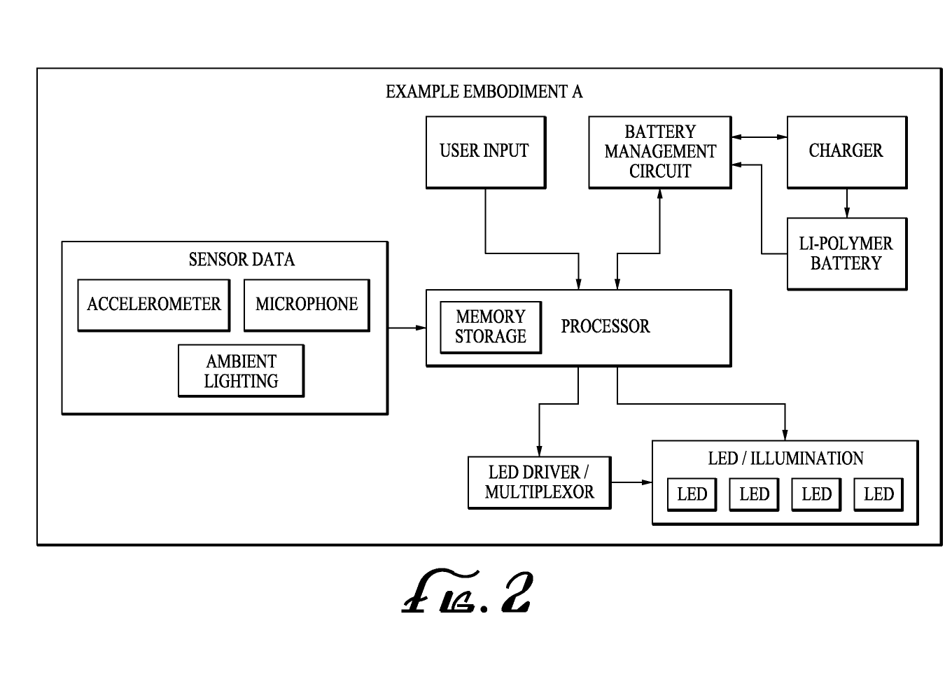

Referring now to FIG. 2, one non-limiting embodiment of a system and method for dynamic jewelry is shown in block diagram. By way of illustration and not of limitation, FIG. 2 discloses the system as applied in the context of a piece of jewelry. Furthermore, FIG. 2 is but one of many possible embodiments of the system in the context of a bracelet, consisting of more or fewer elements than disclosed in FIG. 2.

Continuing with FIG. 2, the system and method may preferably receive data by way of either its sensors or through user input, or both. As for input by sensors, the system can incorporate but does not have to incorporate a microphone, ambient lighting sensor, and/or accelerometer. Other embodiments of the system can include more or fewer sensor elements, including but not limited to biometric, environmental, wired or wireless sensors. The data from these sensors is transmitted to the processor, where it is either temporarily or permanently stored in the processor's memory storage. The processor then processes this data and transmits either directly to the light emitting diode(s) (LEDs) or to an LED driver or a multiplexer, which then direct the LEDs on the bracelet.

FIG. 2 also discloses a pathway whereby user input data is transmitted to the processor, where it is either temporarily or permanently stored in the processor's memory storage. The processor then processes this data and transmits it to an LED driver or a multiplexer, or both, or suitable equivalent, which then directs the LEDs or other light forms, to illuminate.

FIG. 2 further discloses the interplay between the system's processor and its battery management circuit, its charger, and its Li-Polymer Battery.

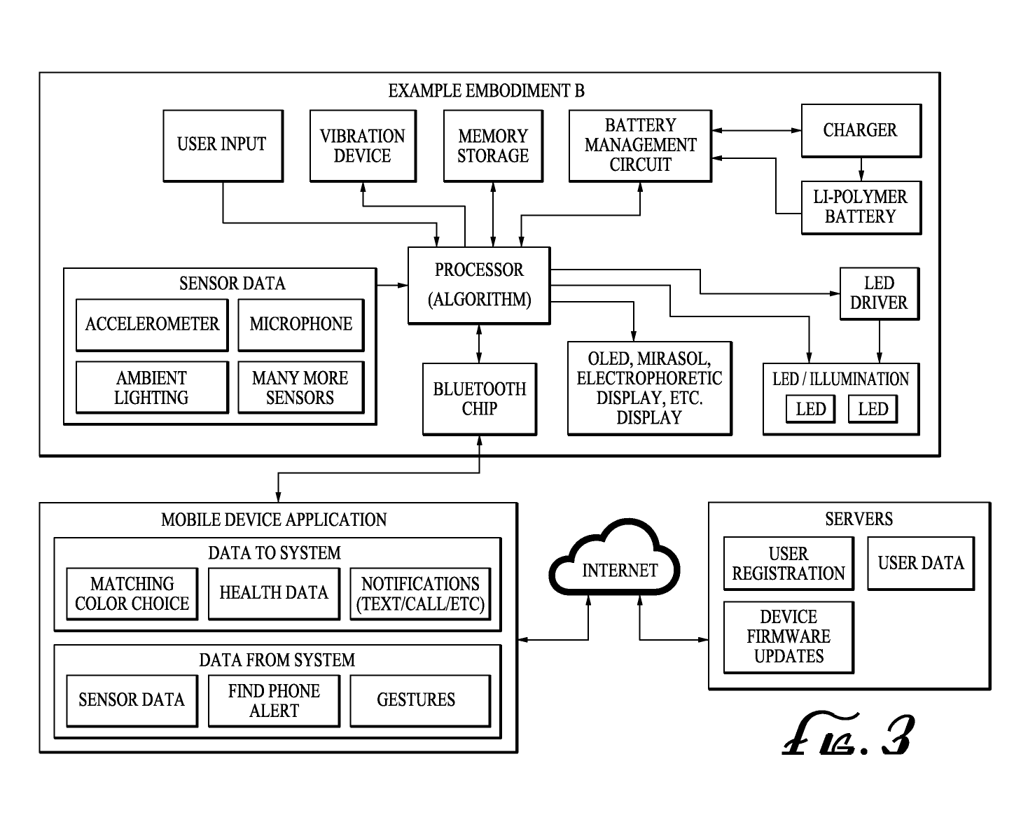

Referring now to FIG. 3, another non-limiting embodiment of the system and method is disclosed in block diagram. In the embodiment shown, the processor can receive data from many different sources. After receiving the data, the processor transmits instructions to the organic light emitting diodes (OLEDs), interferometric modulator display, electrophoretic ink, or any other suitable display, to the mobile device application, and/or to the LEDs via the LED driver/multiplexer/processor.

FIG. 3 further discloses that one source and/or pathway of this data is from Sensor Data. In the embodiment shown, sensors such as an accelerometer, a microphone, an ambient lighting detector, or any of a myriad other sensors such as environmental sensors or biometric sensors, transmit data to the processor, where the data is processed and the processor then transmits instructions to the organic light emitting diodes, interferometric modulator display, electrophoretic ink, or any other suitable display, to the mobile device application, and/or to the LEDs via the LED driver/multiplexer/processor.

FIG. 3 further discloses that one source and/or pathway of this data is from User Input Data. In the embodiment shown, user input data is transmitted to the processor, where the data is processed and the processor then transmits instructions to the organic light emitting diodes, interferometric modulator display, electrophoretic ink, or any other suitable display, to the mobile device application, and/or to the LEDs via the LED driver/multiplexer/processor.

FIG. 3 further discloses that in one embodiment, data originating with the system processor can direct a vibration device to vibrate according to a pattern or sequence as composed by the present invention. The system generates these patterns by applying the algorithms and other processing sequences of the system and mapping these sequences onto these vibration patterns.

FIG. 3 further discloses that one source and/or pathway of this data is from memory storage. In the embodiment shown, data from memory storage is transmitted to the processor, where the processor uses this data to write instructions and/or otherwise process this data. In the embodiment shown, the process can also work in the reverse, such that written information from the memory storage is read by the processor. Based on the result of either of these pathways, or a dynamic interplay of the two, the processor then transmits instructions to the organic light emitting diodes, interferometric modulator display, electrophoretic ink, or any other suitable display, to the mobile device application, and/or to the LEDs via the LED driver/multiplexer/processor. The processor also transmits data back to the memory storage that directs the memory storage to store, delete, or alter stored data.

FIG. 3 further discloses that one source and/or pathway of data is from a battery management circuit, which is in turn linked to a charger and a Li-Polymer battery or similar battery element. Data from the battery management circuit is transmitted to the processor, where the processor processes the data and changes its instructions to the organic light emitting diodes, interferometric modulator display, electrophoretic ink, or any other suitable display, to the mobile device application, and/or to the LEDs via the LED driver/multiplexer/processor. The processor also transmits data back to the battery management circuit that directs the battery management circuit to store or release charge, or otherwise interact with its power source.

FIG. 3 further discloses that one source and/or pathway of this data is from a Bluetooth chip or its equivalent or equivalent system. In the embodiment shown, the Bluetooth chip or its equivalent or equivalent system receives data from a mobile device application, which in turn receives data from various sources, including but not limited to the internet, which in turn receives data from various sources, including but not limited to data from servers.

Continuing with FIG. 3, data from the Bluetooth chip or its equivalent or equivalent system comes to the processor via a two-step pathway. First, data from servers concerning user registration, user data, and device firmware data is transmitted via the internet to a mobile device application, such as could be installed on a smartphone. Then, the mobile device application communicates with the Bluetooth chip or its equivalent, the smartphone, and with the internet to process various forms of data. In the embodiment shown, data can flow from the mobile device application to the system, and data can flow from the system to the mobile device application. Examples of the information flowing to the mobile device application from the system could include, but are not limited to, sensor data, a “find phone alert,” and data regarding user gestures. Examples of data flowing to the system from the mobile phone application could include, but are not limited to, data concerning outfit color selection and color matching data, user health data, and wireless communication data such as a call or text. In addition, data from the Bluetooth chip or its equivalent could include music, sound, biometric, movement, or other data to which the processor applies its algorithms or other processing methods and generates illumination patterns in conformity.

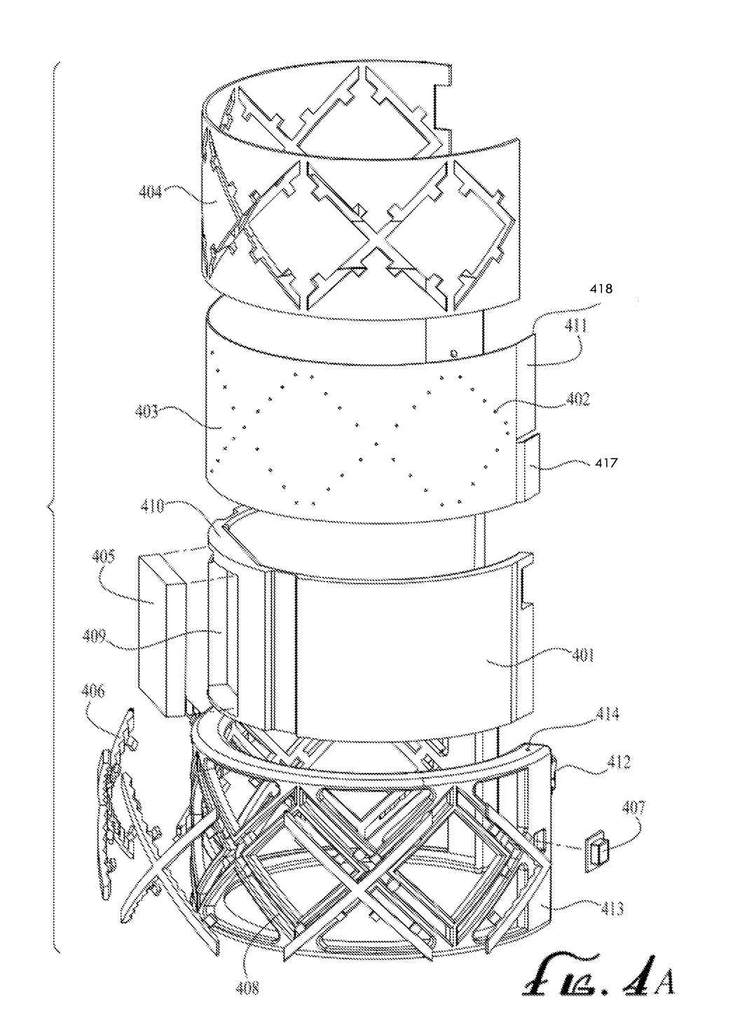

Referring now to FIG. 4A, one non-limiting embodiment of the system and method is disclosed in exploded diagram form. In the embodiment depicted, by way of illustration and not of limitation, a back enclosure 410 is attached to bottom housing 401. Back enclosure 410 provides the point of attachment for a straight battery 405 or a curved battery 415 in, into, or on battery slot 409. Back enclosure 410, in some embodiments, could contain one or more biometric sensors (not pictured). Flex circuit board 403 provides the attachment point for light emitting diodes (LEDs) 402. Insulator 404 may be aligned with the flex circuit board 403 and light emitting diodes 402 as depicted. One or more sensors 418 may be attached to sensor area 411. One or more processors 417 are connected to flex circuit board 403. LED diffusers 406 are attached to outer housing 413. Outer housing 413 also contains a microphone hole 414 for a microphone (not pictured). Outer housing 413 contains a micro USB charging port 412, user input button 407, and design cutouts 408.

Referring now to FIG. 4B, one non-limiting embodiment of the system and method is disclosed in exploded diagram form. In the embodiment depicted, by way of illustration and not of limitation, curved battery 415 and insulator/diffuser 416 are depicted in conjunction with bottom housing 401, flex circuit board 403, light emitting diodes 402, sensor area 411, micro USB charging port 412, outer housing 413, design cutouts 408, user input button 407.

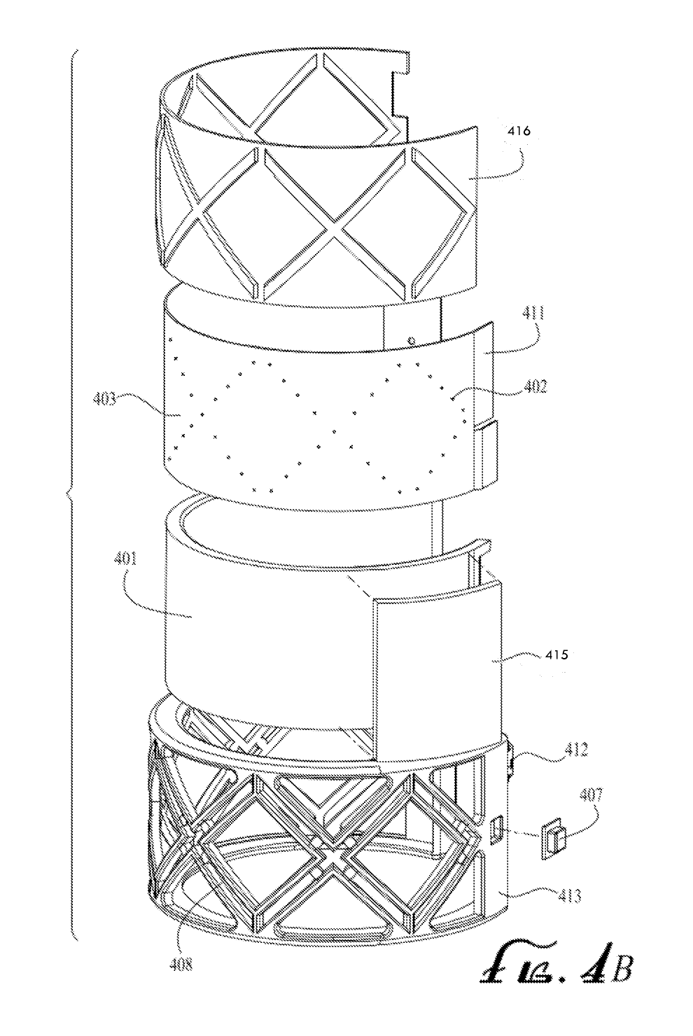

Referring now to FIG. 5, a side view of an exploded view of non-limiting Embodiment C of the system and method as applied or adapted to a curved device for dynamic jewelry is depicted. In the embodiment depicted, by way of illustration and not of limitation, light diffuser 501 is arranged above or on top of light pipe 502, which rests in or is attached to light pipe slot 506. Jewelry finish 503 is preferably but not required to be smooth and made of either metal or plastic. Microphone hole 504 and button hole 505 are located in jewelry finish 503.

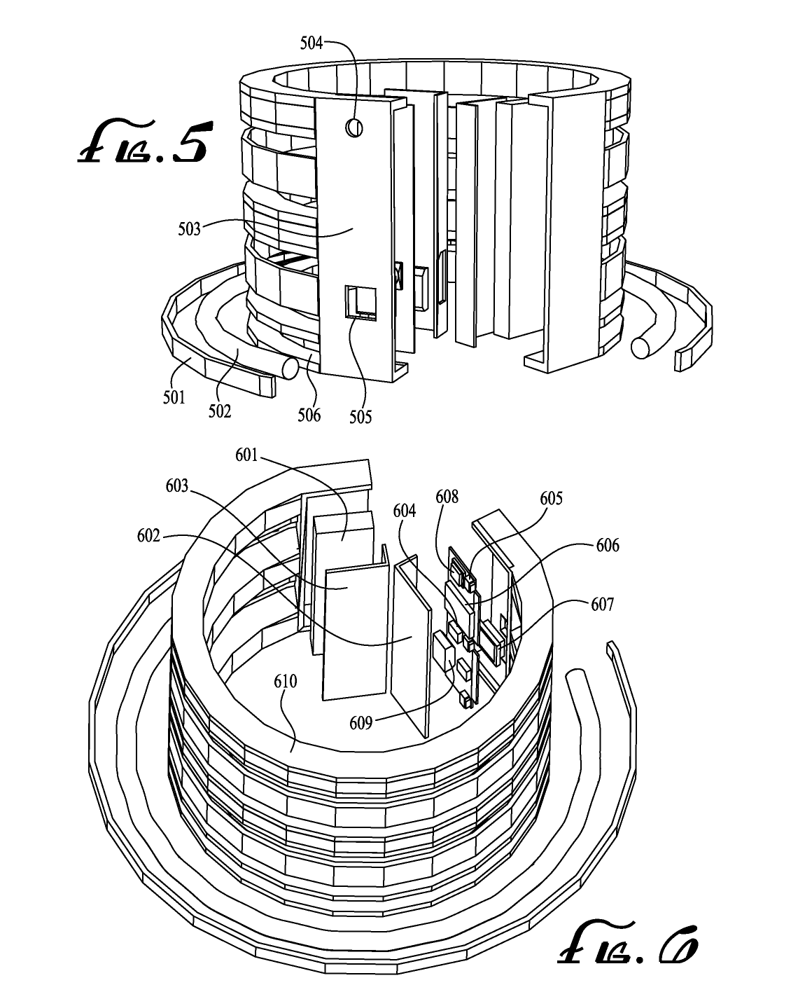

Referring now to FIG. 6. a top view of an exploded view of non-limiting Embodiment C of the system and method as applied or adapted to a curved device for dynamic jewelry is depicted. In the embodiment depicted, a battery 601 is located adjacent to a battery enclosure lid 603. On board sensors 608, including but not limited to a microphone, accelerometer, and light sensor, are located on a circuit board 604, which can be a flex circuit board, a rigid circuit board, a rigid-flex circuit board, or equivalent. The circuit board 604 with on board sensors 608 is located adjacent to an electronics enclosure 602. User input button 607 is located in, on, or around jewelry finish 503 and aligns with button hole 505. Charging input 609 is depicted as accepting a micro USB, but alternate embodiments could accommodate wireless charging. Top casing 610 may enclose one or more light pipes 501.

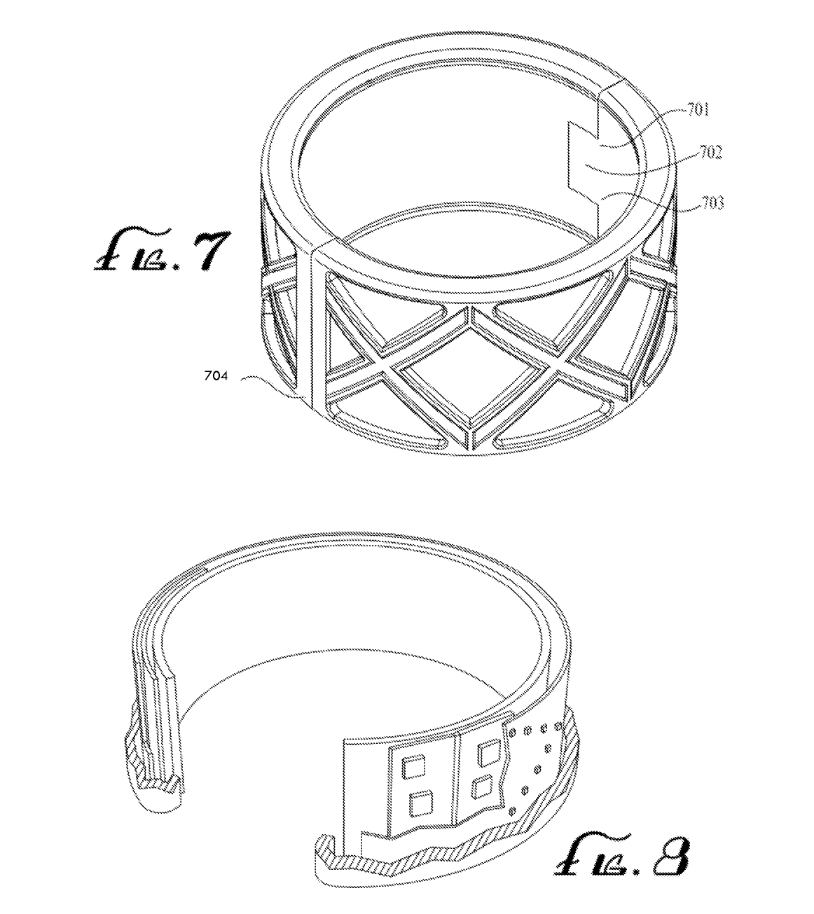

Referring now to FIG. 7. one non-limiting embodiment of the disclosure disclosing the system and method as applied or adapted to a curved device for dynamic jewelry is depicted. In the embodiment depicted, a hinge 701 houses a connector 702 that may preferably be tubular and may preferably facilitate wired communication between any circuitry, processors, sensors, illumination elements, or other elements of the system and method present on either side of the hinge. The hinge 701 may preferably contain a spring loaded element 703. The depicted embodiment may preferably contain a clasp 704 that allows for detachably connecting the two distal ends of the embodiment shown in

FIG. 7, “distal” referring to the ends opposite the hinge.

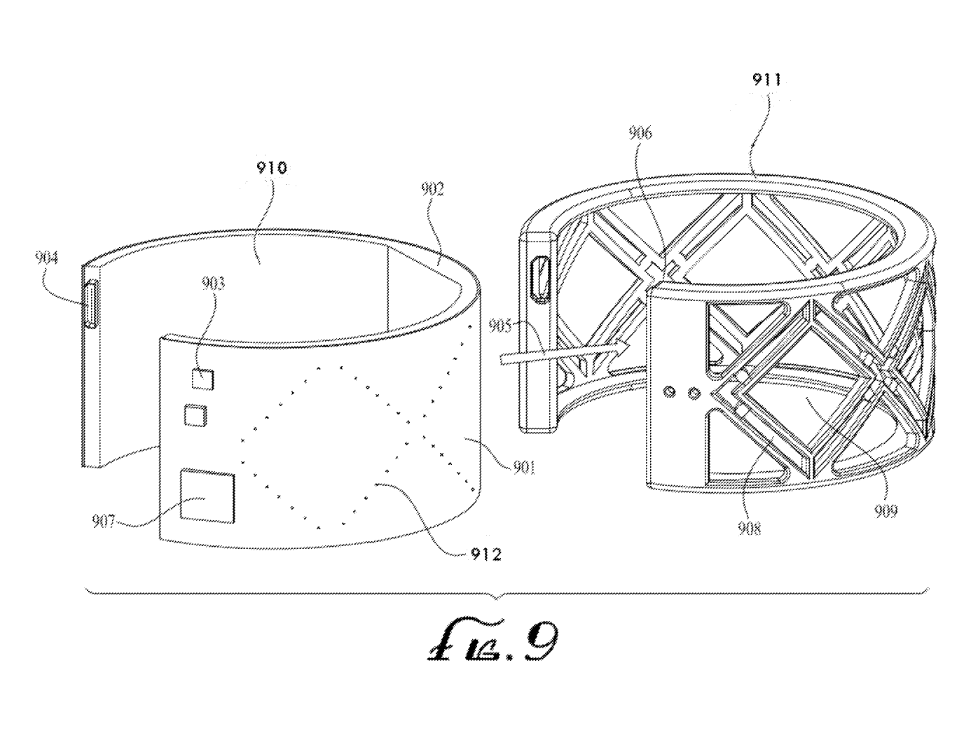

Referring now to FIG. 8. a non-limiting embodiment of the disclosure disclosing a side view of a layered structure of the system and method as applied or adapted to a curved embodiment of the disclosure device for dynamic jewelry is depicted. The embodiment depicted discloses an alternate layered structure for the elements disclosed in the present disclosure, including but not limited to, FIG. 4A, FIG. 4B, FIG. 5, FIG. 6, FIG. 7 and FIG. 9.

Referring now to FIG. 9, a non-limiting embodiment of the disclosure disclosing the system and method as applied or adapted to a curved device for dynamic jewelry depicting the circuitry as separated from the exterior housing is shown. In the embodiment shown, an inner layer 910 may preferably provide the base for flex circuit board 901, battery enclosure 902, and charging input 904. Charging input 904 is depicted as configured to receive a micro USB charging input, but also may be configured for wireless charging. On board sensors 903 are attached to flex circuit board 901, and may preferably include one or more of the sensor elements disclosed in the present disclosure. LEDs 912 and on board processor 907 are attached to flex circuit board 901. Directional arrow 905 indicates that the assembly of flex circuit board 901 and its attachments along with battery enclosure 902 fits inside jewelry piece 911. Jewelry piece 911 also includes microphone hole 906, cutouts for the LEDs 912, and may preferably also include decorative elements inserted in decorative element area 909.

What has been described is a new and improved system and method for dynamic jewelry, thereby overcoming the limitations and disadvantages inherent in the related art.

Although the present invention has been described with a degree of particularity, it is understood that the present disclosure has been made by way of example and that other versions are possible. As various changes could be made in the above description without departing from the scope of the invention, it is intended that all matter contained in the above description or shown in the accompanying drawings shall be illustrative and not used in a limiting sense. The spirit and scope of the appended claims should not be limited to the description of the preferred versions contained in this disclosure.

All features disclosed in the specification, including the claims, abstracts, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means” for performing a specified function or “step” for performing a specified function should not be interpreted as a “means” or “step” clause as specified in 35 U.S.C. §112.

While the system and method has been disclosed in connection with a number of embodiments shown and described in detail, various modifications should be readily apparent to those of skill in the art.

What is claimed is:

1. A dynamic jewelry system, comprising:
(a) a housing containing at least a first layer, a second layer, and a third layer,
(b) said first layer comprising a base with a first end and a second end,
(c) said second layer containing at least one circuit board and at least one battery element, said circuit board and said battery element attached to said base, said circuit board containing at least one light emission element and at least one processor element, wherein said light emission element and said processor element are attached to said circuit board; and
(d) said third layer comprising an external layer having a first end and a second end, said third layer containing design elements arranged so as to allow said light emission elements to be visible to a human eye from a position outward of said jewelry device, and said third layer's first end and second end attached to the first end and second end of said base, thereby concealing said second and third layers from said human eye in said position.

2. The system of claim 1, wherein said second layer contains at least one light pipe attached to said circuit board, wherein said light pipe is illuminated by at least one light emitting diode.

3. The system of claim 1, wherein said device is curved.

4. The system of claim 1, wherein the system of claim 1 comprises a first portion and a second portion, said first portion containing a first portion first end and a first portion second end, said second portion containing a second portion first end and a second portion first end, each portion containing at least one flex circuit board, said first portion first end and said second portion first end connected to either end of a two-ended hinge, said hinge containing a tubular cavity, a cable extending through said tubular cavity, said cable having a first end and a second end, said first end of said cable connected to said flex circuit board of said first portion and said second end of said cable connected to said flex circuit board of said second portion.

5. A method for dynamic jewelry, comprising:
providing at least one circuit board element, at least one processor element, at least one battery element, at least one light emission element, and at least one sensor element, said processor element being in a communicating arrangement with said sensor element, said battery element, and said light emission element, said battery element being in powering arrangement with said processor element, said sensor element, and said light emission element,
capturing information using one or more of said sensor elements,
transmitting said information from said sensor element to said processor element via an information signal,
processing said information signal in said processor element using one or more algorithms to create a light emission signal based on said processing,
sending said light emission signal along said circuit board from said processor element to said light emission element; and
illuminating said light emission element according to said light emission signal.

6. The method of claim 5, wherein said method operates on a curved piece of jewelry.

7. The method of claim 5, wherein said light emission element is at least one light emitting diode.

8. The method of claim 5, wherein said circuit board is a flex circuit board.

9. The method of claim 5, wherein said circuit board is a rigid circuit board.

10. The method of claim 5, wherein said circuit board is a rigid-flex circuit board.

11. The method of claim 5, wherein said sensor element is a biometric sensor.

12. The method of claim 5, wherein said sensor element is an environmental sensor.

13. The method of claim 5, wherein said sensor element is an accelerometer.

14. The method of claim 5, wherein a Bluetooth chip captures information and transmits said information to said processor element via an information signal.

15. The method of claim 5, wherein an action by a user that directly inputs information into said method substitutes for the action of said sensor element.

16. The method of claim 5, wherein a memory storage device substitutes for the action of said sensor element.

17. The method of claim 5, wherein a battery management device substitutes for the action of said sensor element, said battery management device comprising:
i. a charger,
ii. a battery, and
iii. a battery management circuit

18. The method of claim 5, wherein said light emission element is at least one organic light emitting diode.

19. The method of claim 5, wherein said processor element receives said information, uses one or more algorithms to create a display signal based on said processing, sends said display signal along said circuit board element from said processor element to an electrophoretic ink display element, and said electrophoretic ink display element configures at least one electrophoretic ink display according to said display signal.

20. The method of claim 5, wherein said processor element processes said information signal to create a vibration signal, said processor element transmits said vibration signal to a vibration element, and said vibration element vibrates according to said vibration signal.
